(19) United States
(12) Patent Application Publication
(10) Pub. No.: US 2019/0097070 A1
(43) Pub. Date: Mar. 28, 2019

(54) SHEET FOR SOLAR BATTERY MODULE, AND SOLAR BATTERY MODULE

(71) Applicant: Toray Industries, Inc., Tokyo (JP)

(72) Inventors: Yu Shibata, Otsu-shi (JP); Kentaro Mori, Otsu-shi (JP)

(21) Appl. No.: 16/081,736

(22) PCT Filed: Feb. 3, 2017
(86) PCT No.: PCT/JP2017/003946

§ 371 Date: Aug. 31, 2018

(30) Foreign Application Priority Data
Mar. 4, 2016 (JP) 2016-041790

(51) Int. Cl. H01L 31/049; H01L 31/054; H02J 7/35

(52) U.S. Cl. CPC H01L 31/049; H02J 7/35; H01L 31/0547

(57) ABSTRACT

A sheet for solar cell modules is provided with an infrared transmitting layer, and an infrared reflecting layer containing a polyester resin as a main component, wherein the sheet has a reflectance not lower than 20% in a wavelength region of 400-600 nm, and the infrared reflecting layer contains 5-40 mass % of an incompatible polymer with respect to 100 mass % of all components constituting the infrared reflecting layer.

### TECHNICAL FIELD

This disclosure relates to a sheet for a solar battery module and to solar battery module.

### BACKGROUND

In recent years, the greenhouse effect due to increases of carbon dioxide is expected to cause global warming. Therefore, clean energy that does not emit carbon oxide is demanded. Under such circumstances, solar light power generation that uses solar battery modules is drawing great attention because of its high safety and versatility. Generally, a solar battery module has a configuration in which a cover member, an obverse side encapsulant, solar battery cells that perform photoelectric conversion, a reverse side encapsulant, and a back sheet for the solar battery module are stacked in that order from the light receiving surface side. Furthermore, inside the solar battery module, sheets that secure insulation and tapes that fix the solar battery cells are used in many places.

Usually, the external appearance of solar battery cells is black. Therefore, to avoid impairing the external appearance of a solar battery module installed outdoors, it is preferred that various sheets for use in solar battery modules be black.

In general, to make various sheets for use in solar battery modules black, carbon black that is high in coloration power and low in cost is used. However, use of carbon black in various sheets for use in a solar battery module can result in decreased reflectance due to light absorption, increased temperatures due to infrared absorption and the like so that power generation performance of the solar battery module decreases.

As countermeasures against the foregoing problems, a method in which a perylene-based pigment described in Japanese Unexamined Patent Publication (Kokai) No. 2011-249670 is used instead of carbon black and a method in which white sheets having a plurality of pigments and voids as described in Japanese Unexamined Patent Publication (Kokai) No. 2015-15414 are used in a combination have been disclosed.

However, as for the method described in JP '670, although it is possible to retain black color design characteristic while lessening light absorption, the reflecting performance in the infrared region is still insufficient so that inferiority in power generation efficiency when the sheet is in a solar battery module is problematic. Furthermore, as for the method described in JP '414, although a white sheet containing voids can improve the reflecting performance in an infrared region, the reflecting performance in the infrared region is still insufficient.

It could therefore be helpful to provide a sheet for solar battery modules that, despite being black, is excellent in reflectiveness for light in an infrared region and a solar battery module excellent in power generation efficiency and external appearance.

### SUMMARY

We thus provide:

(1) A sheet for a solar battery module including an infrared transmitting layer and an infrared reflecting layer containing a polyester resin as a main component, wherein an average reflectance in a wavelength range of 400 nm to 600 nm is 20% or less and the infrared reflecting layer contains an incompatible polymer in an amount greater than or equal to 5 mass % and less than or equal to 40 mass % relative to 100 mass % of all components that constitute the infrared reflecting layer.
(2) The sheet for a solar battery module according to (1), characterized in that the average reflectance in a wavelength range of 800 nm to 1,200 nm is 85% or greater.
(3) The sheet for a solar battery module according to (1) or (2), characterized in that the infrared transmitting layer contains an infrared transmitting coloration agent.
(4) The sheet for a solar battery module according to any one of (1) to (3), characterized in that the infrared transmitting layer contains a perylene-based pigment.
(5) The sheet for a solar battery module according to any one of (1) to (4), characterized in that the infrared transmitting layer contains a phthalocyanine based blue pigment and/or a dioxazine based violet pigment and a diketopyrrolopyrrole based red pigment.
(6) The sheet for a solar battery module according to any one of (1) to (5), characterized in that the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.
(7) The solar battery module in which a cover member, an obverse side encapsulant, a solar battery cell, a reverse side encapsulant, and a back sheet for the solar battery module are positioned in that order from a light receiving side, the solar battery module being characterized by including the sheet for a solar battery module according to any one of (1) to (6) and by the infrared transmitting layer being positioned more to the light receiving surface side than the infrared reflecting layer is.
(8) The solar battery module according to (7), characterized in that the back sheet for the solar battery module is the sheet for a solar battery module according to any one of (1) to (6).

A sheet for a solar battery module that, despite being black, is excellent in reflectiveness for light in an infrared region and a solar battery module excellent in power generation efficiency and external appearance can be obtained.

### BRIEF DESCRIPTION OF THE DRAWINGS

FIG. 1 is a schematic sectional view obtained when a solar battery module according to an example is cut by a plane perpendicular to a light receiving surface (an example in which the sheet for a solar battery module is used as a back sheet for a solar battery module).

FIG. 2 is a schematic sectional view obtained when a solar battery module according to an example is cut by a plane perpendicular to the light receiving surface (an example in which the sheet for a solar battery module is used as an insulating sheet).

FIG. 3 is a schematic sectional view obtained when a solar battery module according to an example is cut by a plane perpendicular to the light receiving surface (an example in which the sheet for a solar battery module is used as a positional deviation prevention tape to prevent positional deviation of a solar battery cell).

### EXPLANATION OF NUMERALS

1: Solar battery module
2: Back sheet for a solar battery module
3: Infrared transmitting layer
4: Infrared reflecting layer
5: Reverse side encapsulant
6: Obverse side encapsulant
7: Cover member
8: Solar battery cell
9: Positional deviation prevention tape
10: Obverse side extraction electrode
11: Reverse side extraction electrode
12: Insulating sheet
13: Tackiness agent layer

### DETAILED DESCRIPTION

Next, the sheet for a solar battery module and the solar battery module will be described.

The sheet for a solar battery module is characterized by including an infrared transmitting layer and an infrared reflecting layer that contains a polyester resin as a main component, wherein an average reflectance in a wavelength range of 400 nm to 600 nm is 20% or less and the infrared reflecting layer contains an incompatible polymer in an amount greater than or equal to 5 mass % and less than or equal to 40 mass % relative to 100 mass % of all components that constitute the infrared reflecting layer.

From the viewpoint of favorably achieving both design characteristic and power generation efficiency when the sheet for a solar battery module is in a solar battery module, it is important that the sheet have an infrared transmitting layer and that the average reflectance in the wavelength range of 400 nm to 600 nm be 20% or less.

The infrared transmitting layer refers to a layer whose average transmittance is 50% or greater when irradiated with light in a wavelength range of 800 nm to 1,200 nm. The average transmittance refers to an average transmittance obtained by measuring the amount of light transmitted through the layer (hereinafter, sometimes referred to as the amount of transmitted light) and the amount of light that a light source emits (hereinafter, sometimes referred to as reference quantity of light) in a measurement wavelength range of 800 nm to 1200 nm and dividing the amount of transmitted light by the reference quantity of light and multiplying by 100.

The average reflectance in the wavelength range of 400 nm to 600 nm refers to an average reflectance obtained when the sheet for a solar battery module is irradiated from the infrared transmitting layer side with light in the wavelength range of 400 nm to 600 nm. The average reflectance refers to an average relative reflectance measured using a white plate of barium sulfate as a reference.

The infrared transmitting layer is positioned more to the light receiving surface side than the infrared reflecting layer described later is to the light receiving surface side when in a solar battery module. Therefore, since the sheet for a solar battery module includes the infrared transmitting layer, the sheet when in a solar battery module can lessen the decrease of the light in the infrared region (hereinafter, sometimes referred to simply as infrared) that reaches the infrared reflecting layer. As a result, the decrease of the power generation efficiency of the solar battery module can be lessened.

Then, generally, when the average reflectance in the wavelength range of 400 nm to 600 nm decreases, the colors observed by the naked eye become dark. Furthermore, color battery cells usually have black external appearances. Therefore, as the average reflectance of the sheet for a solar battery module in the wavelength range of 400 nm to 600 nm is 20% or less, the difference in color shade between the infrared transmitting layer of the sheet for a solar battery module and a solar battery cell that appears when they are superimposed over each other can be lessened. As a result, in a solar battery module, the hue observed from the light receiving surface side provides a sense of unity and the design characteristic becomes good.

From the view point of lessening the difference in color shade when the infrared transmitting layer of the sheet for a solar battery module and a solar battery cell are superimposed over each other, it is preferable that the average reflectance in the wavelength range of 400 nm to 600 nm be 20% or less and it is more preferable that the average reflectance be 10% or less. Furthermore, the lower the average reflectance in the wavelength range of 400 nm to 600 nm, the closer to black the external appearance of the sheet for the solar battery module observed from the infrared transmitting layer side (hereinafter, sometimes referred to as external appearance of the infrared transmitting layer). Therefore, the lower limit value of the average reflectance in the wavelength range of 400 nm to 600 nm is not particularly restricted. However, an average reflectance of about 0.5% is sufficient.

The method of causing the average reflectance in the wavelength range of 400 nm to 600 nm to be 20% or less is not particularly restricted as long as the advantageous effects are not impaired. For example, a method in which an infrared transmitting coloration agent described later is contained in the infrared transmitting layer can be cited. More concretely, increasing the content of the infrared transmitting coloration agent in the infrared transmitting layer can lower the average reflectance in the wavelength range of 400 nm to 600 nm and decreasing the content of the infrared transmitting coloration agent in the infrared transmitting layer can raise the average reflectance in the wavelength range of 400 nm to 600 nm.

It is preferable that the infrared transmitting layer contain an infrared transmitting coloration agent, from the viewpoint of favorably achieving both the design characteristic and the power generation efficiency when the sheet is in a solar battery module. The infrared transmitting coloration agent refers to a coloration agent that achieves a level of 75% or greater in the average transmittance obtained by performing measurement by the foregoing method, with the measurement wavelength range at 800 nm to 1200 nm, when incorporated in a sheet which contains 95 mass % of polyethylene terephthalate and 5 mass % of the coloration agent relative to 100 mass % of all components and whose thickness is 75 μm. Due to the infrared transmitting coloration agent, it becomes possible to make the external appearance closer to black without impairing the characteristics (infrared transmitting property) of the infrared transmitting layer.

As concrete examples of the infrared transmitting coloration agents, for example, perylene-based pigments, phthalocyanine based blue pigments, and dioxazine based violet pigments as well as diketopyrolopyrrole based red pigments, azo pigments and the like can be cited.

As for the content of the infrared transmitting coloration agent in the infrared transmitting layer, from the viewpoint of favorably achieving both the design characteristics when in a solar battery module and the film formability and the economy at the time of production of the sheet for solar battery modules, it is preferable that the content be greater than or equal to 0.01 mass % and less than or equal to 30 mass % and it is more preferable that the content be greater than or equal to 1 mass % and less than or equal to 20 mass % when all components that constitute the infrared transmitting layer are assumed to make 100 mass %.

The thickness of the infrared transmitting layer is not particularly restricted as long as it does not impair the advantageous effects. However, from the viewpoint of making the external appearance of the infrared transmitting layer closer to black, it is preferable that the thickness be 2 μm or greater and it is more preferable that the thickness be 5 μm or greater. Usually, the greater the thickness of the infrared transmitting layer, the closer to black the external appearance thereof, provided that the content of the infrared transmitting coloration agent in the infrared transmitting layer is constant. Therefore, there is no upper limit to the thickness of the infrared transmitting layer. From the viewpoint of attaining the advantageous effects, a thickness of about 100 μm is sufficient. Incidentally, the content of the infrared transmitting coloration agent in the infrared transmitting layer being constant means that the content of the infrared transmitting coloration agent in 100 mass % of all components that constitute the infrared transmitting layer, not the absolute amount of the infrared transmitting coloration agent, is constant.

As for the infrared transmitting coloration agent, use of only one component and use of a mixture of a plurality of components are both permissible as long as the advantageous effects are not impaired. When a plurality of kinds are mixed and used, the content of the infrared transmitting coloration agents is calculated not for each component, but as a total for all the infrared transmitting coloration agents.

In the sheet for a solar battery module, it is preferable that the infrared transmitting layer contain a perylene-based pigment, from the viewpoint of the design characteristic and the power generation efficiency when the sheet is in a solar battery module. The perylene-based pigment, despite being a pigment that appears black, does not have high infrared absorption property like carbon black. Therefore, adoption of such a mode makes it possible to make the external appearance close to black without impairing the characteristics (infrared transmitting property) of the infrared transmitting layer. Then, use of such a sheet for a solar battery module can improve the design characteristic of the solar battery module without impairing its power generation efficiency.

The kind of the perylene-based pigment in the sheet for a solar battery module is not particularly restricted as long as the advantageous effects are not impaired. For example, a compound represented by any one of formulae (I) to (III), or the like, can be used. As long as the advantageous effects are not impaired, use of only one kind of perylene-based pigment and use of a mixture of a plurality of kinds thereof are both permissible.

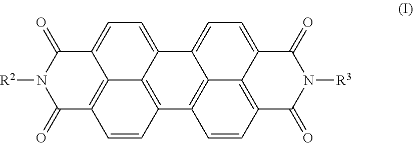

R² and R³ are the same as or different from each other and are each a butyl group, a phenylethyl group, a methoxy ethyl group, or a 4-methoxyphenyl methyl group.

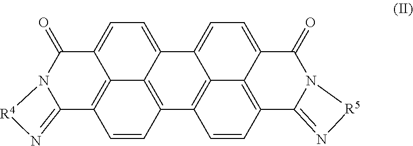

R⁴ and R⁵ are the same as or different from each other and are each a phenylene group, a 3-methoxyphenylene group, a 4-methoxyphenylene group, a 4-ethoxyphenylene group, an alkylphenylene group whose carbon number is 1 to 3, a hydroxyphenylene group, a 4,6-dimethylphenylene group, a 3,5-dimethylphenylene group, a 3-chlorophenylene group, a 4-chlorophenylene group, a 5-chlorophenylene group, a 3-bromophenylene group, a 4-bromophenylene group, a 5-bromophenylene group, a 3-fluorophenylene group, a 4-fluorophenylene group, a 5-fluorophenylene group, a naphthylene group, a naphthalenediyl group, a pyridylene group, a 2,3-pyridinediyl group, a 3,4-pyridinediyl group, a 4-methyl-2,3-pyridinediyl group, a 5-methyl-2,3-pyridinediyl group, a 6-methyl-2,3-pyridinediyl group, a 5-methyl-3,4-pyridinediyl group, 4-methoxy-2,3-pyridinediyl group, or a 4-chloro-2,3-pyridinediyl group.

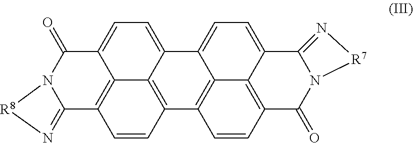

R⁶ and R⁷ are the same as or different from each other and are each a phenylene group, a 3-methoxyphenylene group, a 4-methoxyphenylene group, a 4-ethoxyphenylene group, an alkylphenylene group whose carbon number is 1 to 3, a hydroxyphenylene group, a 4,6-dimethylphenylene group, a 3,5-dimethylphenylene group, a 3-chlorophenylene group, a 4-chlorophenylene group, a 5-chlorophenylene group, a 3-bromophenylene group, a 4-bromophenylene group, a 5-bromophenylene group, a 3-fluorophenylene group, a 4-fluorophenylene group, a 5-fluorophenylene group, a naphthylene group, a naphthalenediyl group, a pyridylene group, a 2,3-pyridinediyl group, a 3,4-pyridinediyl group, a 4-methyl-2,3-pyridinediyl group, a 5-methyl-2,3-pyridinediyl group, a 6-methyl-2,3-pyridinediyl group, a 5-methyl-3,4-pyridinediyl group, a 4-methoxy-2,3-pyridinediyl group, or a 4-chloro-2,3-pyridinediyl group.

Furthermore, as for the foregoing perylene-based pigment, commercially sold products such as “‘Paliogen’ (registered trademark) Black S 0084” and “‘Lumogen’ (registered trademark) Black FK 4280” (which are both made by BASF company) can be used. “‘Paliogen’ (registered trademark) Black S 0084” is a perylene-based pigment in which R² and R³ in general formula (I) are phenylethyl groups and “‘Lumogen’ (registered trademark) Black FK 4280” is a perylene-based pigment in which R⁶ and R⁷ in formula (III) are phenylene groups.

It is preferable that the infrared transmitting layer contain a phthalocyanine based blue pigment and/or a dioxazine based violet pigment, and a diketopyrrolopyrrole based red pigment, from the viewpoint of the design characteristic and the power generation efficiency when the sheet is in the solar battery module. Adoption of such a mode makes it possible to make the external appearance closer to black without impairing the characteristics (infrared transmitting property) of the infrared transmitting layer. Then, the use of such a sheet for a solar battery module can improve the design characteristic of the solar battery module without impairing the power generation efficiency thereof.

The phthalocyanine based blue pigment is a pigment having a phthalocyanine skeleton; concretely, Pigment Blue 15, Pigment Blue 15:1, Pigment Blue 15:2, Pigment Blue 15:3, Pigment Blue 15:4, Pigment Blue 15:6, Pigment Blue 16, Pigment Blue 17:1, Pigment Blue 75, Pigment Blue 79, Pigment Green 7 and the like can be cited. In the sheet for a solar battery module, it is preferable to use at least one of Pigment Blue 15, Pigment Blue 15:1, Pigment Blue 15:2, Pigment Blue 15:3, Pigment Blue 15:4, and Pigment Blue 75, from the viewpoint of the weather resistance and the color shade when the sheet is in the solar battery module.

The dioxazine based violet pigment is a pigment having a dioxazine skeleton; concretely, Pigment Violet 23, Pigment Violet 37 and the like can be cited.

The diketopyrrolopyrrole based red pigment is a pigment having a diketopyrrolopyrrole skeleton; concretely, Pigment Red 254, Pigment Red 255, Pigment Red 264, Pigment Red 272 and the like can be cited. In the sheet for a solar battery module, it is preferable to use Pigment Red 254 and/or Pigment Red 264, from the viewpoint of the weather resistance and the color shade when the sheet is in the solar battery module.

The phthalocyanine based blue pigment, the dioxazine based violet pigment, and the diketopyrrolopyrrole based red pigment may be used in any mode as long as the advantageous effects are not impaired, provided that any one of a combination of the phthalocyanine based blue pigment and the diketopyrrolopyrrole based red pigment, a combination of the dioxazine based violet pigment and the diketopyrrolopyrrole based red pigment, a combination of the phthalocyanine based blue pigment, the dioxazine based violet pigment, and the diketopyrrolopyrrole based red pigment is maintained.

For example, these pigments can be used together with the foregoing perylene-based pigment. Furthermore, as long as a combination of pigments mentioned above is maintained, use of only one kind of phthalocyanine based blue pigment and use of a mixture of a plurality of kinds thereof are both permissible. This applies in the same manner to the dioxazine based violet pigment and the diketopyrrolopyrrole based, too.

It is important that the sheet for a solar battery module have an infrared reflecting layer containing a polyester resin as a main component, from the viewpoint of the power generation efficiency and the heat resistance when the sheet is in the solar battery module.

The polyester resin refers to a resin obtained by condensation polymerizing a diol or its derivative (hereinafter, these are sometimes collectively referred to as diols and the like) and a dicarboxylic acid, a hydroxy carboxylic acid, or a derivative thereof (hereinafter, these are sometimes collectively referred to as dicarboxylic acids and the like). Hereinafter, of the components incorporated in a polymer chain by condensation polymerization, those originating from diols and the like are sometimes referred to as diol-or-the-like components and those originating from dicarboxylic acids and the like are sometimes referred to as dicarboxylic-acid-or-the-like components. Containing a polyester resin as a main component refers to the polyester resin in the layer exceeding 50 mass % where all components constituting the layer are assumed to make 100 mass %. Furthermore, the infrared reflecting layer refers to a layer that has an average reflectance of 70% or greater when irradiated with light in a wavelength range of 800 nm to 1,200 nm. The average reflectance refers to an average relative reflectance measured by using a white plate of barium sulfate as a reference.

The dicarboxylic acid or the like and the diol or the like to obtain the polyester resin may be either a single component or a plurality of kinds of components. The polyester resin in which the dicarboxylic acid or the like and the diol or the like are each a single component will be referred to as a homopolyester resin and the polyester resin in which at least one of the dicarboxylic acid or the like and the diol or the like is a plurality of kinds of components will be referred to as a copolyester resin.

As the dicarboxylic acid or the like, for example, terephthalic acid, isophthalic acid, phthalic acid, naphthalene dicarboxylic acid, adipic acid, sebacic acid, 2,6-naphthalene dicarboxylic acid, 5-sodium sulfoisophthalate, derivatives of these or the like can be cited.

As the diol or the like, for example, ethylene glycol, trimenthylene glycol, tetramethylene glycol, cyclohexanedimethanol, diethylene glycol, neopentyl glycol, polyalkylene glycol, derivatives of these or the like can be cited.

The polyester resin is not particularly limited as long as the advantageous effects are not impaired; for example, polyethylene terephthalate, polyethylene naphthalate, polymethylene terephthalate, polytetramethylene terephthalate, polyethylene-p-oxybenzoate, poly-1,4-cyclohexylenedimethylene terephthalate, polyethylene-2,6-naphthalene dicarboxylate or the like can be used singly or in a mixture. Among these, from the viewpoint of water resistance, durability, chemical resistance and the like, it is preferable to use polyethylene terephthalate or polyethylene naphthalate singly or in a mixture and it is most preferable to use polyethylene terephthalate singly.

The polyethylene terephthalate refers to a homopolyester resin or a copolyester resin that contains an ethylene glycol component in an amount greater than or equal to 55 mol % and less than or equal to 100 mol % in a total of 100 mol % of the diol-or-the-like component and that contains a terephthalic acid component in an amount greater than or equal to 55 mol % and less than or equal to 100 mol % in a total of 100 mol % of the dicarboxylic acid-or-the-like component. Furthermore, the polyethylene naphthalate refers to a homopolyester resin or a copolyester resin that contains an ethylene glycol component in an amount greater than or equal to 55 mol % and less than or equal to 100 mol % in a total of 100 mol % of the diol-or-the-like component and that contains a 2,6-naphthalene dicarboxylic acid component in an amount greater than or equal to 55 mol % and less than or equal to 100 mol % in a total of 100 mol % of the dicarboxylic acid-or-the-like component.

Furthermore, when a plurality of kinds of polyester resins are mixed and used, the content of the polyester resin in the layer is calculated by summing all the polyester resins.

Furthermore, various additives, for example, an antioxidant, an antielectrostatic agent and the like, can be added into the polyester resin.

It is important that the infrared reflecting layer contain an incompatible polymer in an amount greater than or equal to 5 mass % and less than or equal to 40 mass % relative to 100 mass % of all components that constitute the infrared reflecting layer. The incompatible polymer refers to a resin that is incompatible with the polyester resin that is a main component.

As the infrared reflecting layer contains 5 mass % or more of an incompatible polymer relative to 100 mass % of all components that constitute the infrared reflecting layer, the polyester resin is stretched more than the incompatible polymer during film-forming stretch so that space is formed at an interface between the polyester resin and the incompatible polymer and therefore voids are sufficiently formed in the infrared reflecting layer. Hence, the infrared reflecting performance of the sheet obtained will improve. On the other hand, as the infrared reflecting layer contains 40 mass % or less of the incompatible polymer relative to 100 mass % of all components that constitute the infrared reflecting layer, the sheet can retain a sufficient mechanical strength and therefore film formation stability is maintained.

From the foregoing viewpoint, it is preferable that the content of the incompatible polymer in the infrared reflecting layer be greater than or equal to 8 mass % and less than or equal to 35 mass % relative to 100 mass % of all components that constitute the infrared reflecting layer.

From the viewpoint of favorably achieving both the infrared reflecting performance and the film formation stability of the sheet, it is preferable that the incompatible polymer be at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene, and it is more preferable that the incompatible polymer be poly-4-methylpentene-1 and/or a cyclic olefin copolymerized resin, and it is even more preferable that the incompatible polymer be poly-4-methylpentene-1. The cyclic olefin copolymerized resin is a copolymer obtained by copolymerizing ethylene and at least one kind of cyclic olefin. It is preferable that the cyclic olefin be a bicycloalkene and/or a tricycloalkene. Poly-4-methylpentene-1 will hereinafter be sometimes referred to simply as polymethylpentene.

It is preferable that the incompatible polymer be a polymer whose melting point is 180° C. or greater, from the viewpoint of improving the infrared reflecting performance of the sheet for a solar battery module. As the melting point of the incompatible polymer is 180° C. or greater, the dense voids are formed in the infrared reflecting layer. Therefore, the infrared reflecting performance of the sheet for a solar battery module improves so that the decrease of the mechanical strength can be curved.

Furthermore, from the viewpoint of improving the infrared reflecting performance of the sheet for a solar battery module, it is preferable that the infrared reflecting layer contain a dispersing assistant agent for the incompatible polymer (hereinafter, sometimes referred to simply as a dispersing assistant agent). Because the infrared reflecting layer contains a dispersing assistant agent, the dense voids are formed in the infrared reflecting layer. Therefore, the infrared reflecting performance of the sheet for a solar battery module improves and the decrease of the mechanical strength can also be curbed. The dispersing assistant agent is a compound that has an advantageous effect of facilitating dispersion of the incompatible polymer.

The dispersing assistant agent is not particularly restricted as long as the advantageous effects are not impaired. However, from the viewpoint of the close packing of voids formed in the infrared reflecting layer, it is preferable that the dispersing assistant agent be a thermoplastic polyester elastomer or a polyalkylene glycol, and it is more preferable that the dispersing assistant agent be polyalkylene glycol, and it is even more preferable that the dispersing assistant agent be polyethylene glycol. Furthermore, to improve the dispersibility of the incompatible polymer, a copolymer of polybutylene terephthalate and polytetramethylene glycol, or the like, may be further used.

The content of the dispersing assistant agent in the infrared reflecting layer is not particularly restricted as long as the advantageous effects are not impaired. However, from the viewpoint of favorably achieving both improvements in the infrared reflecting performance and the dispersibility of the incompatible polymer and maintenance of mechanical characteristics of the sheet, it is preferable that, when all components that constitute the infrared reflecting layer are assumed to make 100 mass %, the content of the dispersing assistant agent be greater than or equal to 3 mass % and less than or equal to 40 mass %, and it is more preferable that the content of the dispersing assistant agent be greater than or equal to 5 mass % or less than or equal to 30 mass %.

Adoption of such a mode will extremely reduce the diameter of the dispersing size and increase the tier number of voids per thickness of the infrared reflecting layer. Therefore, the infrared reflecting performance of the sheet for a solar battery module improves and the decrease of the mechanical strength can be curbed. When the content of the dispersing assistant agent exceeds 40 mass % relative to 100 mass % of all components that constitute the infrared reflecting layer, the effect of further reducing the dispersion diameter sometimes cannot be obtained.

The dispersing assistant agent can also be prepared as a master polymer (master chip) by adding the dispersing assistant agent in the infrared reflecting layer-forming polymer beforehand.

Furthermore, the infrared reflecting layer may contain inorganic particles to improve the weather resistance or the like when incorporated in the solar battery module, as long as the advantageous effects are not impaired. It is preferable that the content of the inorganic particle in the infrared reflecting layer be greater than or equal to 5 mass % and less than or equal to 20 mass % relative to 100 mass % of all components that constitute the infrared reflecting layer and it is more preferable that the content of the inorganic particle be greater than or equal to 10 mass % and less than or equal to 20 mass %.

Because the infrared reflecting layer contains 5 mass % or more of the inorganic particle relative to 100 mass % of all components, the weather resistance when the infrared reflecting layer is in a solar battery module will improve. On the other hand, because the infrared reflecting layer contains 20 mass % or less of the inorganic particle relative to 100 mass % of all components, the characteristics of the infrared reflecting layer-forming polymer are sufficiently maintained.

The inorganic particle is not particularly restricted as long as the advantageous effects are not impaired. For example, calcium carbonate, magnesium carbonate, zinc carbonate, titanium oxide, zinc oxide, cerium oxide, magnesium oxide, barium sulfate, zinc sulfide, calcium phosphate, alumina, mica, mica titanium, talc, clay, kaolin, lithium fluoride, calcium fluoride and the like may be used singly or in a combination of two or more species. Among these, from the viewpoint of weather resistance and stability, it is preferable to use titanium oxide and it is more preferable to use a rutile-type titanium oxide. When two or more kinds of inorganic particles are combined and used, the content of the inorganic particles is calculated by totaling the amounts of all the inorganic particles.

As for the aforementioned inorganic particle, it is preferable that the number average secondary particle diameter measured by a laser diffraction method according to JIS Z8825:2013 be greater than or equal to 0.05 μm and less than or equal to 7 μm, and it is more preferable that the number average secondary particle diameter be greater than or equal to 0.1 μm and less than or equal to 3 μm. With the number average secondary particle diameter of the inorganic particle being greater than or equal to 0.05 μm, a dispersibility in the infrared reflecting layer is maintained so that the sheets obtained are more homogeneous. Furthermore, with the number average secondary particle diameter of the inorganic particle being less than or equal to 7 μm, the voids formed become small in size so that the infrared reflecting performance of the sheet for a solar battery module improves.

It is preferable that the average reflectance in the wavelength range of 800 nm to 1,200 nm be 85% or greater, from the viewpoint of the power generation performance when the sheet is in a solar battery module. Light in the wavelength range of 800 nm to 1,200 nm (infrared) contributes to power generation by the solar battery module. Therefore, as the average reflectance in the wavelength range of 800 nm to 1,200 nm is 85% or greater, it becomes possible to further improve the power generation performance when the sheet is in the solar battery module.

The method of causing the average reflectance in the wavelength range of 800 nm to 1,200 nm to be 85% or greater is not particularly limited as long as the advantageous effects are not impaired. However, for example, a method in which the content of the incompatible polymer in the infrared reflecting layer is adjusted or a method in which the thickness of the infrared reflecting layer is adjusted can be cited.

Concretely, increasing the content of the incompatible polymer in the infrared reflecting layer will increase void nuclei and therefore increase the tier number of voids to allow the average reflectance in the wavelength range of 800 nm to 1,200 nm to be improved. Furthermore, by increasing the thickness of the infrared reflecting layer in a certain range as described below, the average reflectance in the wavelength range of 800 nm to 1,200 nm can be improved.

From the viewpoint of improving the average reflectance in the wavelength range of 800 nm to 1,200 nm, it is preferable that the thickness of the infrared reflecting layer be 50 μm or greater, and it is more preferable that the thickness be 75 μm or greater, and it is even more preferable that the thickness be 125 μm or greater. The upper limit of the thickness of the infrared reflecting layer is not particularly restricted as long as the advantageous effects are not impaired. However, since a thickness exceeding 300 μm is not expected to further improve the reflecting performance, a thickness of about 300 μm is sufficient.

It is preferable that the infrared reflecting layer contain a light stabilizing agent from the viewpoint of improving the weather resistance when the sheet is in the solar battery module. It is preferable that the content of the light stabilizing agent be 0.1 to 5 mass % in 100 mass % of all components of the infrared reflecting layer, and it is more preferable that the content thereof be 0.5 to 5 mass %, and it is particularly preferable that the content thereof be 1 to 5 mass %. As the content of the light stabilizing agent is 0.1 mass % or greater relative to 100 mass % of all components of the infrared reflecting layer, the weather resistance improves. As the content thereof is 5 mass % or less, the decrease in the power generation efficiency due to coloration of the infrared reflecting layer caused by the light stabilizing agent can be curbed.

The light stabilizing agent is not particularly restricted as long as the advantageous effects are not impaired. However, it is preferable to select a light stabilizing agent that is excellent in heat resistance, highly compatible with the foregoing polyester resin, capable of uniform dispersion and causes less coloration and therefore does not adversely affect the reflection characteristic of the infrared reflecting layer and the polyester resin. For example, various light stabilizing agents, including ultraviolet absorbing agents such as salicylic acid based ones, benzophenone-based ones, benzotriazole-based ones, cyanoacrylate based ones, triazine based ones or the like, and ultraviolet stabilization agent such as hindered amine-based ones, can be employed. More concrete employment examples are as follows:
Salicylic acid based ultraviolet absorbing agents: p-t-butylphenyl salicylate, p-octylphenyl salicylate and the like
Benzophenone-based ultraviolet absorbing agents: 2,4-dihydroxybenzophenone, 2-hydroxy-4-methoxybenzophenone, 2-hydroxy-4-methoxy-5-sulfobenzophenone, 2,2′-4,4′-tetrahydroxybenzophenone, 2,2′-dihydroxy-4-methoxybenzophenone, 2,2′-dihydroxy-4,4′-dimethoxybenzophenone, bis(2-methoxy-4-hydroxy-5-benzoylphenyl)methane and the like
Benzotriazole-based ultraviolet absorbing agents: 2-(2′-hydroxy-5′-methylphenyl)benzotriazole, 2-(2′-hydroxy-5′-butylphenyl)benzotriazole, 2-(2′-hydroxy-3′,5′-di-t-butylphenyl)benzotriazole, 2-(2′-hydroxy-3′-t-butyl-5′methylphenyl)-5-chlorobenzotriazole, 2-(2′-hydroxy-3′,5′-di-t-methylphenyl)-5-chlorobenzotriazole, 2-(2′-hydroxy-3′,5′-di-t-butylphenyl)-5-chlorobenzotriazole, 2-(2′-hydroxy-5′-t-octylphenyl)benzotriazole, 2-(2′-hydroxy-3′,5′-di-t-amylphenyl)benzotriazole, 2,2′methylene bis[4-(1,1,3,3-tetramethylbutyl)-6-(2H-benzotriazole-2-yl)phenol], 2(2′hydroxy-5′-methacryloxyphenyl)-2H-benzotriazole, 2-[2′-hydroxy-3′-(3″,4″,5″,6″-tetrahydro phthalimido methyl)-5′methylphenyl]benzotriazole and the like
Cyanoacrylate based ultraviolet absorbing agents: ethyl-2-cyano-3,3′-diphenyl acrylate and the like
Triazine based ultraviolet absorbing agents: 2-(2,4-dihydroxyphenyl)-4,6-bis-(2,4-dimethylphenyl)-1,3,5-triazine, 2,4-bis[2-hydroxy-4-butoxyphenyl]-6-(2,4-dibutoxyphenyl)-1,3,5-triazine and the like
Ultraviolet absorbing agents other than those mentioned above: 2-ethoxy-2′-ethyloxalic acid bisanilide, 2-(4,6-diphenyl-1,3,5-triazine-2-yl)-5-[(hexyl)oxy]-phenol, 2-(4,6-bis(2,4-dimethylphenyl)-1,3,5-triazine-2-yl)-5-hydroxyphenyl and the like
Hindered amine-based ultraviolet stabilizing agents: bis(2,2,6,6-tetramethyl-4-piperidyl)sebacate, dimethyl succinate-1-(2-hydroxyethyl)-4-hydroxy-2,2,6,6-tetramethylpiperidine polycondensate and the like
Ultraviolet stabilizing agents: nickel bis(octylphenyl)sulfide, [2-thiobis(4-t-octyl phenolate)]-n-butylaminenickel, nickel complex-3,5-di-t-butyl-4-hydroxybenzyl-phosphate monoethylate, nickel-dibutyl dithiocarbamate, 2,4-di-t-butylphenyl-3′,5′-di-t-butyl-4′-hydroxy benzoate, 2,4-di-t-butylphenyl-3′,5′-di-t-butyl-4′-hydroxy benzoate and the like.

Among these light stabilizing agents, it is preferable to use at least one of 2,2′-4,4′-tetrahydroxybenzophenone, bis(2-methoxy-4-hydroxy-5-benzoylphenyl)methane, 2,2′-methylene bis[4-(1,1,3,3-tetramethylbutyl)-6-(2H-benzotriazole-2-yl)phenol], and 2-(4,6-diphenyl-1,3,5-triazine-2-yl)-5-[(hexyl)oxy]-phenol, from the viewpoint of excellence in the compatibility with polyester resin. Furthermore, in terms of performance, it is preferable to use a triazine based ultraviolet absorbing agent.

As for the light stabilizing agent, it is possible to either singly use an agent or use two or more kinds of agents together, as long as the advantageous effects are not impaired. When two or more kinds of agents are used together, the content thereof is calculated by summing those of all the light stabilizing agents.

The layer construction of the sheet for a solar battery module may be in a mode in which the infrared transmitting layer and the infrared reflecting layer are in contact or may also be in a mode in which another layer such as an adhesion-facilitating layer, is present between the infrared transmitting layer and the infrared reflecting layer, as long as the advantageous effects are not impaired. However, because when infrared radiation entering the infrared reflecting layer or infrared radiation reflected from the infrared reflecting layer is absorbed by the interlayer layer, the power generation efficiency of the solar battery module sometimes decreases, it is more preferable that the layer construction be in a mode in which the infrared transmitting layer and the infrared reflecting layer are in contact.

A stacking method of obtaining the sheet for a solar battery module is not particularly limited as long as the advantageous effects are not impaired. For example, a co-extrusion method, a coating method, a dry laminate method, a melt laminate method or the like can be preferably used.

The co-extrusion method refers to a method in which raw materials of the infrared transmitting layer that constitute the infrared transmitting layer such as a resin and an infrared transmitting coloration agent (hereinafter, sometimes referred to simply as raw materials of the infrared transmitting layer) are supplied into an extruder (extruder A) and raw materials of the infrared reflecting layer such as a polyester resin and an incompatible polymer (hereinafter, sometimes referred to simply as raw materials of the infrared reflecting layer) are supplied into another extruder (extruder B) and, using a T-die two-layer mouthpiece, molten materials are extruded, each in a layer, from the extruder A and the extruder B, and are stacked so that the layer obtained due to the extruder A is used as an infrared transmitting layer and the layer obtained due to the extruder B is used as an infrared reflecting layer.

The coating method refers to a method in which a coating agent that contains the raw materials of the infrared transmitting layer are coated onto a film that corresponds to the infrared reflecting layer so that the infrared transmitting layer and the infrared reflecting layer are laminated.

The dry laminate method refers to a method in which a film formed from raw materials of the infrared transmitting layer by using a T-die extruder or the like is stacked, by using an adhesive, with a film that corresponds to the infrared reflecting layer.

The melt laminate method refers to a method in which a composition obtained by melting the raw materials of the infrared transmitting layer are melt-extruded directly on and therefore stacked on a film that corresponds to the infrared reflecting layer.

The resin that constitutes the infrared transmitting layer can be appropriately selected by taking into consideration the stacking method and the close contact characteristic with respect to a encapsulant for a solar battery module described below as long as the advantageous effects are not impaired. For example, the foregoing polyester resin, acrylic resins such as a poly(meth)acrylic resin, polyolefin resins such as polyethylene and polypropylene, fluorinebased resins such as polyvinyl fluoride and polyvinylidene fluoride, ethylene-vinyl acetate copolymers and the like can be used singly or in a mixture.

Next, a production method for the sheet for a solar battery module will be concretely described, using as an example the production of a sheet for a solar battery module that contains polyethylene terephthalate as a main component by a co-extrusion method. However, our methods are not limited to this.

As a composition used to obtain an infrared reflecting layer, polyethylene terephthalate, polymethylpentene (incompatible polymer), polyethylene glycol (dispersing assistant agent), polybutylene terephthalate, and polytetramethylene glycol copolymer (dispersing assistant agent) are mixed. The thus obtained composition is dried, supplied into an extruder A heated to a temperature of 270 to 300° C., and then extruded to a T-die two-layer mouthpiece. Separately, as a composition for an infrared transmitting layer, an infrared transmitting coloration agent such as a perylene-based pigment, and polyethylene terephthalate are mixed. The thus obtained composition is dried, supplied into an extruder B heated to a temperature of 270 to 300° C., and then similarly extruded to the T-die two-layer mouthpiece.

Next, the compositions obtained from the extruder A and the extruder B are each extruded in the form of a layer by using the T-die two-layer mouthpiece so that a sheet-shaped article in which the infrared reflecting layer and the infrared transmitting layer are stacked on each other is obtained.

This sheet-shaped article is brought into close contact with a drum whose surface temperature is 10 to 60° C. by electrostatic force to be cooled and solidified so that a non-oriented sheet is obtained. After that, the obtained unstretched film is guided to a group of rolls heated to a temperature of 80 to 120° C., and longitudinally stretched to 2.0 to 5.0 times in a machine direction, and then cooled by a group of rolls having a temperature of 20 to 50° C. so that a uniaxially oriented sheet is obtained. Subsequently, the obtained uniaxially oriented sheet, while being held at both ends thereof with clips, is guided to a tenter and laterally stretched to 2.0 to 5.0 times in a transverse direction in an atmosphere heated to a temperature of 90 to 140° C. The machine direction refers to the direction in which the sheet advances during sheet production and the transverse direction refers to the direction parallel to a transport surface for the sheet and orthogonal to the machine direction.

As for the stretch ratio, the sheet is stretched to 2.0 to 5.0 times both longitudinally and laterally. It is preferable that the area ratio thereof (the longitudinal stretch ratio×the lateral stretch ratio) be 9 to 16 times. When the area ratio is less than 9 times, the infrared reflecting performance of the obtained sheet is sometimes low. Conversely, when the area ratio exceeds 16 times, the sheet is sometimes liable to tear when stretched. To give the sheet biaxially stretched in this manner a planarity and a dimensional stability, the sheet is thermally fixed at a temperature of 150 to 230° C. in the tenter. After being uniformly gradually cooled, the sheet is cooled to room temperature and wound up to obtain the sheet for a solar battery module.

The solar battery module is a solar battery module in which a cover member, an obverse side encapsulant, a solar battery cell, a reverse side encapsulant, and a back sheet for the solar battery module are positioned in that order from the light receiving surface and is characterized by including the sheet for a solar battery module and by the infrared transmitting layer being positioned more to the light receiving surface side than the infrared reflecting layer is.

The solar battery module is a solar battery module in which a cover member, an obverse side encapsulant, a solar battery cell, a reverse side encapsulant, and a back sheet for the solar battery module are positioned in that order from the light receiving surface side, and it is important for the solar battery module to include the sheet for a solar battery module. As the solar battery module includes the sheet for a solar battery module, the design characteristic can be improved without impairing the power generation efficiency.

Furthermore, as for the solar battery module, from the viewpoint of the design characteristic, it is important that the infrared transmitting layer be positioned more to the light receiving surface side than the infrared reflecting layer is. As the infrared transmitting layer is positioned more to the light receiving surface side than the infrared reflecting layer is, the difference in color shade between the solar battery cell portion and the portion constituted by the sheet for a solar battery module is small when the solar battery module is observed form the light receiving surface side so that the design characteristic of the solar battery module improves.

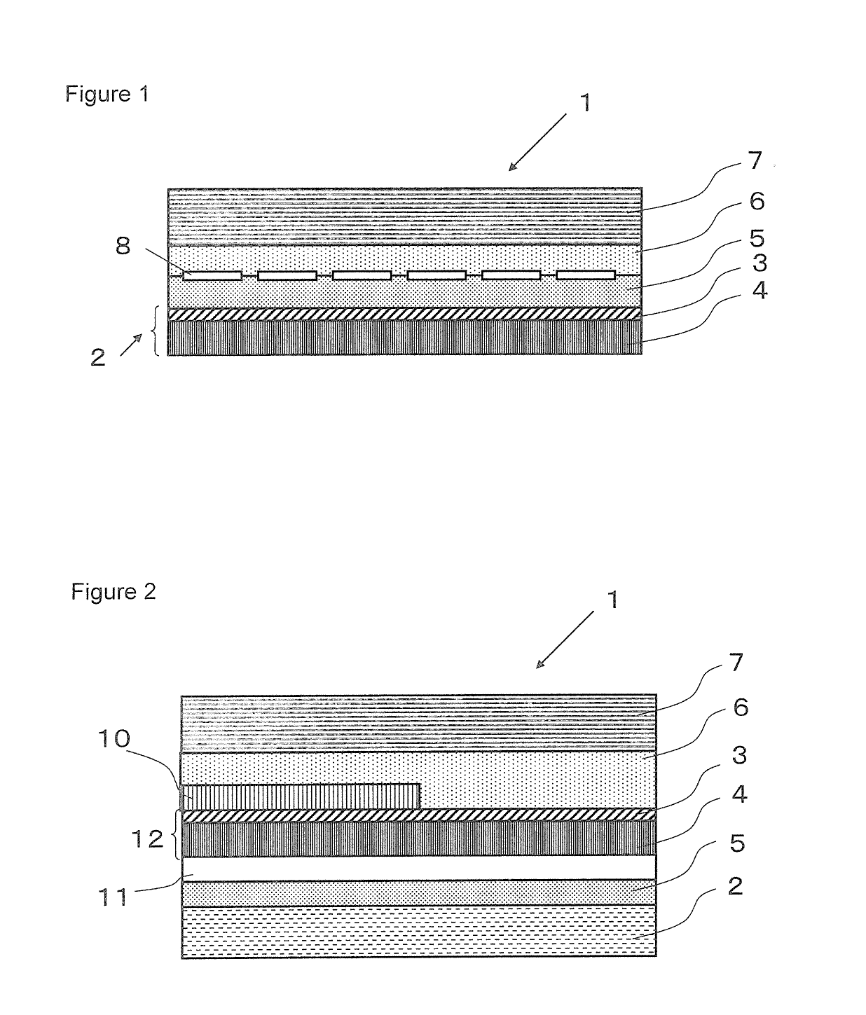

As a preferred mode of the solar battery module, an example as illustrated in FIG. 1 in which a back sheet for a solar battery module is the sheet for a solar battery module can be cited. The back sheet for a solar battery module entirely covers the reverse surface of the solar battery module (the surface opposite to the light receiving surface). Therefore, by using the sheet for a solar battery module so that the infrared transmitting layer is at the light receiving surface side, the design characteristic of the solar battery module can be improved without impairing its power generation efficiency.

It is preferable that the thickness of the solar battery module in this mode (the thickness from the cover member obverse surface to the reverse surface of the back sheet for the solar battery module) be in the range greater than or equal to 475 μm and less than or equal to 12.5 cm. When the thickness of the solar battery module is less than 475 μm, there is concern that the mechanical strength of the solar battery module may become insufficient. Furthermore, when the thickness of the solar battery module exceeds 12.5 cm, there is concern that the weight of the solar battery module may increase so that the workability at the time of installing the solar battery module may deteriorate.

Hereinafter, the solar battery module will be described while concrete modes of the solar battery module are illustrated with the drawings.

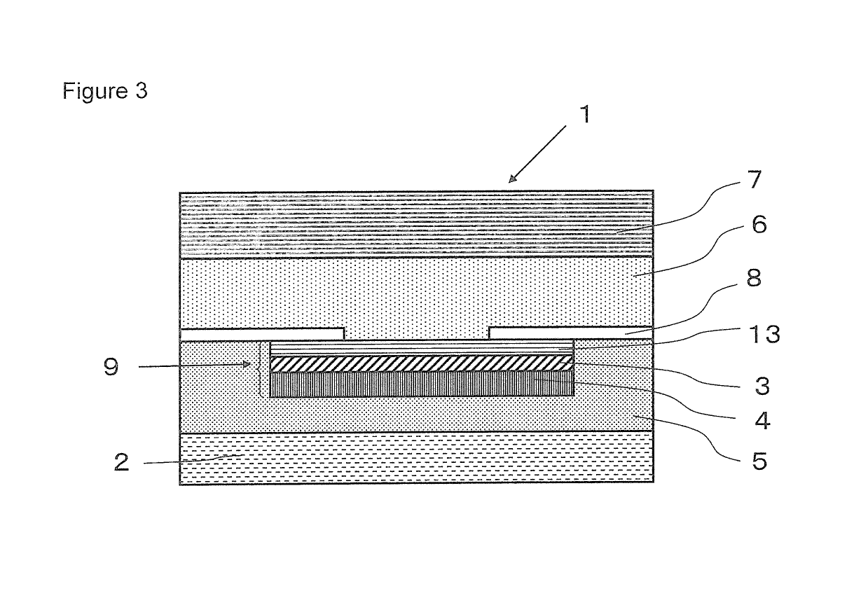

FIGS. 1 to 3 are schematic sectional views obtained when an example of a solar battery module is cut by a plane perpendicular to a light receiving surface. FIG. 1 illustrates an example in which the sheet for a solar battery module is used as a back sheet for a solar battery module. FIG. 2 illustrates an example in which the sheet for a solar battery module is used as an insulating sheet. FIG. 3 illustrates an example in which the sheet for a solar battery module is used as a positional deviation prevention tape to prevent the positional deviation of a solar battery cell.

As illustrated in FIG. 1, when the sheet for a solar battery module is used as a back sheet for a solar battery module, a solar battery module 1 has a configuration in which a cover member 7, an obverse side encapsulant 6, a solar battery cell 8, a reverse side encapsulant 5, and a back sheet 2 for a solar battery module are positioned in that order from a light receiving surface side. The back sheet 2 for the solar battery module that corresponds to the sheet for a solar battery module includes the infrared transmitting layer 3 and the infrared reflecting layer 4. At this time, one or a plurality of solar battery cells 8 are connected in series or in parallel by using an electrically conductive material and are installed between the obverse side encapsulant 6 and the reverse side encapsulant 5 so that spaces are formed between adjacent solar battery cells 8 (FIG. 1).

As illustrated in FIG. 2, when the sheet for a solar battery module is used as an insulating sheet, a mode in which an insulating sheet 12 is positioned between an obverse side extraction electrode 10 and a reverse side extraction electrode 11 to prevent electric conduction between the obverse side extraction electrode 10 and the reverse side extraction electrode 11 is preferable.

As illustrated in FIG. 3, when the sheet for a solar battery module is used as a positional deviation prevention tape 9, a solar battery module 1 is provided so that a cover member 7, an obverse side encapsulant 6, a solar battery cell 8, a positional deviation prevention tape 9, a reverse side encapsulant 5, and a back sheet 2 for a solar battery module are positioned in that order from the light receiving surface side, and the positional deviation prevention tape 9 is disposed at a non-light receiving surface side of the solar battery cell 8 so that the infrared transmitting layer 3 is at the light receiving surface side. Because the positional deviation prevention tape 9 needs to be adhered to the solar battery cell 8, it is preferable that a tackiness agent layer 13 that contains an existing tackiness agent such as a rubber based one, an acryl based one, a silicone based one, or an urethane based, be stacked on the infrared transmitting layer 3 and thus used. As for the tackiness agent, a silicone based tackiness agent, among the aforementioned ones, can be preferably used from the viewpoint of heat resistance and weather resistance.

Furthermore, besides the foregoing examples, the solar battery module can include the sheet for a solar battery module provided at a position that is visible from the light receiving surface side and that does not block the solar battery cells, as long as the advantageous effects are not impaired. As the sheet for a solar battery module is included, the design characteristic and improved power generation efficiency due to reflection of light in the infrared region can be expected.

The cover member is a material positioned at the most obverse surface of the solar battery module and constitutes a portion directly irradiated with sun light. The cover member is required to have transmissivity to sun light, electrical insulation property and mechanical strengths to snowfall, wind pressure and the like, weather resistance to acid rain and to temperature, humidity and ultraviolet radiation for long periods and the like, scratch resistance at the time of installation of a solar battery module and against sand and dust and the like.

As a material for the cover member, known materials such as glass or a resin molding, can be used. As resin molding, for example, a polyolefin resin, a poly(meth)acrylic resin, a polycarbonate resin, a polyester resin, a fluorine resin and the like can be cited. Among these materials, glass and polycarbonate can be preferably used from the viewpoint of strength and weather resistance.

It is preferable that the thickness of the cover member be in a range greater than or equal to 50 μm and less than or equal to 10 cm, from the viewpoint of mechanical strength and weight reduction. When the thickness of the cover member less than 50 there is concern that the mechanical strength may be insufficient. Furthermore, when the thickness of the cover member exceeds 10 cm, there is concern that the weight of the solar battery module may increase so that the workability at the time of installing the solar battery module may deteriorate.

As the obverse side encapsulant and the reverse side encapsulant (hereinafter, these will sometimes be collectively referred to as encapsulants) for use in the solar battery module, for example, an ionomer resin, an EVA (ethylene-vinyl acetate copolymerized resin), polyvinyl butyral, a silicone resin, a polyurethane resin, a denaturation polyolefin resin and the like can be cited. Among these, the EVA can be preferably used from the viewpoint of weather resistance, close contact characteristic with respect to other members, and member costs. As for the obverse side encapsulant and the reverse side encapsulant, the same material may be used or different materials may also be used as long as the advantageous effects are not impaired.

It is preferable that the thicknesses of the obverse side encapsulant and the reverse side encapsulant before they are incorporated in a solar battery module be each greater than or equal to 200 μm and less than or equal to 1 cm. When the thickness of the obverse side encapsulant and/or the reverse side encapsulant is below 200 μm, there is concern that a solar battery cell may break because of pressures due to heating or loads of various members for production of solar battery modules. Furthermore, when the thickness of the obverse side encapsulant and/or and the reverse side encapsulant exceeds 1 cm, there is concern that the weight of the solar battery module may increase more than necessary so that the workability at the time of installing the solar battery module may deteriorate.

The solar battery cells are photoelectromotive force elements that convert light energy from sun light into electric energy and the solar battery cells are spaced from each other and arranged in series or in parallel between the obverse side encapsulant and the reverse side encapsulant. In the solar battery module, the kind of solar battery cell is not particularly limited as long as the advantageous effects are not impaired. As the solar battery cells, for example, single crystal silicon type ones, polycrystal type ones, amorphous silicon type ones, compound type ones, organic thin film type ones and the like can be suitably used.

### EXAMPLES

### Evaluation Method for Characteristics

Measurements and evaluations indicated in conjunction with Examples were performed under conditions as indicated below.

### (1) Thickness of Sheet and Thickens of Each Layer

The thickness of sheets for solar battery modules were measured according to JIS C2151:2006. A sheet for a solar battery module was cut in the thickness direction by using a microtome to obtain cut piece samples. The section of each cut piece sample was subjected to three-point imaging at a magnification of 200 times, using a field emission type scanning electron microscope (FE-SEM)S-800 made by Hitachi, Ltd. From images at three points, average values of thicknesses of the layers were taken to calculate the thicknesses of the layers and a total thickness being a total of the thicknesses of the layers.

### (2) Average Reflectance

Sheets for a solar battery module were cut out into 5 cm×5 cm for use as samples. The obtained samples were disposed so that the incidence surface for measurement light was at the infrared transmitting layer side. With a basic construction in which an integrating sphere attached to a spectrophotometer made by Shimadzu Corporation (UV-3150 UV-VIS-NIR Spectrophotometer) was used, measurement of relative average reflectance at wavelengths of 400 nm to 600 nm and of 800 nm to 1,200 nm with respect to reference light was performed. The measurement was performed once, using a standard white plate of barium sulfate that was an accessory of the apparatus as a reference, with the slit being 12 nm, the sampling pitch being 1 nm, and the scan speed being high speed. The obtained value was determined as an average reflectance of the sheet for the solar battery module.

### (3) Average Transmittance

The layers containing a coloration agent were cut out into 5 cm×5 cm for use as samples. The obtained samples were disposed so that the incidence surface for measurement light was at the light receiving surface side when the samples were positioned in modules. With a basic construction in which an integrating sphere attached to a spectrophotometer made by Shimadzu Corporation (UV-3150 UV-VIS-NIR Spectrophotometer) was used, measurement of transmittance at wavelengths of 800 nm to 1,200 nm with respect to reference light was performed. The measurement was performed once, with the slit being 12 nm, the sampling pitch being 1 nm, and the scan speed being high speed. An average value of the obtained transmittances at various wavelengths in the wavelengths of 800 nm to 1,200 nm was determined as an average transmittance.

### (4) Black Color Design Characteristic

Sheets for a solar battery module were cuted out into 5 cm×5 cm for use as samples. The obtained samples were disposed on a standard white plate for apparatus calibration so that the measurement surface was at the infrared transmitting layer side. Using a Handy Spectrophotometer “NF 333” made by NIPPON DENSHOKU INDUSTRIES company, L*, a*, and b* were measured as color tones. The measurement was performed with a D light source and a visual field angle of 2°, and black color design characteristics were calculated according to the following expression. As for the black color design characteristic, smaller values indicate blacker colors.

Black color design characteristic=(L*²+a*²+b*²)^{1/2}

The values of black color design characteristic were determined as follows, and A and B were taken as being passed.

Black color design characteristic less than 30: A

Black color design characteristic greater than or equal to 30 and less than 60: B

Black color design characteristic greater than or equal to 60: C

### (5) Manufacture and Power Generation Amounts of Solar Battery Modules

A flux (H722 made by HOZAN company) was applied by a dispenser to silver electrode portions on the obverse and reverse sides of a polycrystal silicon type solar battery cell (G156M3 made by Gintech company). On the silver electrodes on the obverse and reverse surfaces, wiring members (copper foil SSA-SPS 0.2×1.5 (20), made by Hitachi Cable company) cut into a length of 155 mm were placed so that an end of a wiring member was at a location 10 mm apart from one of ends of the obverse surface-side cell and, on the reverse surface side, symmetry to the obverse surface side was obtained. From the cell reverse surface side, a soldering iron was brought into contact to perform solder welding simultaneously on the obverse surface and the reveres surfaces. Thus, a one-cell string was manufactured.

Next, placement was made such that the machine direction of the aforementioned wiring member protruding from the cell of the manufactured one-cell string and the machine direction of an extraction electrode (copper foil A-SPS 0.23×6.0, made by Hitachi Cable, Ltd.) cut into 180 mm were perpendicular to each other. A superimposed portion between the aforementioned wiring member and the extraction electrode was coated with the aforementioned flux and solder welding was performed. Thus, an extraction electrode-equipped string was manufactured.

Next, a glass of 190 mm×190 mm (3.2 mm-thick white plate heat-treated glass for a solar battery, made by Asahi Glass company) as a cover member, ethylene vinyl acetate of 190 mm×190 mm (a encapsulant of 0.5 mm in thickness, made by SANVIC company) as an obverse side encapsulant, an extraction electrode-equipped string, ethylene vinyl acetate of 190 mm×190 mm (a encapsulant of 0.5 mm in thickness, made by SANVIC company) as a reverse side encapsulant, and a sheet for a solar battery module cut into 190 mm×190 mm which was set in such an orientation that the infrared transmitting layer was positioned between the ethylene vinyl acetate and the infrared reflecting layer were stacked in that order. The obtained stack was set so that the glass contacted the heat plate of a vacuum laminator. Then, vacuum lamination was performed under conditions of a heat plate temperature of 145° C., vacuuming for 4 minutes, pressing for 1 minute, and a retention time of 10 minutes, to obtain a solar battery module. At this time, the extraction electrode-equipped string was set so that the glass surface was at the cell surface side. The obtained solar battery module was subjected to measurement of the maximum power generation amount according to a reference state of JIS C8914:2005, to determine the power generation amount of the solar battery module.

### Polyester Resin

### (A1)

Chip-shaped polyethylene terephthalate

### Coloration Agent

### (B1)

Perylene-based pigment (trade name: “Peliogen” (registered trademark) Black L 0086, made by BASF company)

### (B2)

Phthalocyanine based blue pigment (trade name: Pigment Blue 15:3, made by Tokyo Chemical Industry company)

### (B3)

Diketopyrrolopyrrole based red pigment (trade name: Pigment Red 255, made by Tokyo Chemical Industry company)

### (B4)

Dioxazine based violet pigment (trade name: NX-042 Violet, made by Dainichiseika Color & Chemicals Mfg. company)

### (B5)

Carbon black (trade name: #45L, made by Mitsubishi Chemical company)

### (B6)

Titanium black (trade name: Titanium Black 13 S, made by Mitsubishi Materials Electronic Chemicals company)

B1 to B4 correspond to infrared transmitting coloration agents, and B5 and B6 do not correspond so.

### Dispersing Assistant Agent

### (C1)

A copolymer of 75 mass % of polyethylene terephthalate, polybutylene terephthalate, and polytetramethylene glycol (PBT/PTMG)(trade name: “Hytrel” (registered trademark), made by Du Pont-Toray company)

### (C2)

A polyethylene terephthalate copolymer containing 10 mol % of an isophthalic acid component in the entire dicarboxylic acid-or-the-like component and 5 mol % of polyethylene glycol component having a number-average molecular weight of 1,000 in the entire diol-or-the-like component (PET/I/PEG)

### Incompatible Polymer

### (D1)

### Polymethylpentene

Next, our sheets, modules and methods will be described in detail, using Examples. However, this disclosure is not to be interpreted as being limited by these examples.

### Example 1

The components were prepared and mixed so that A1 made 95 mass % and B1 made 5 mass % when all components constituting the composition were assumed to make 100 mass %. Thus, a composition used to obtain an infrared transmitting layer was obtained. This composition, after being dried under reduced pressure at a temperature of 180° C. for 3 hours, was supplied to the extruder A heated to a temperature of 270 to 300° C. On the other hand, the components were prepared and mixed so that A1 made 75 mass %, C1 made 5 mass %, C2 made 10 mass %, and D1 made 10 mass % when all components constituting the composition were assumed to make 100 mass %. Thus, a composition used to obtain an infrared reflecting layer was obtained. This composition, after being dried at a temperature of 180° C. for 3 hours, was supplied into the extruder B heated to a temperature of 270 to 300° C.

The composition was ejected in a sheet shape from the extruder A and cooled and solidified on a cooling drum whose surface temperature was 25° C. Thus, a non-oriented film was obtained. This was longitudinally stretched to 3.4 times in the machine direction by a group of rolls heated to a temperature of 85 to 98° C., and was cooled by a group of rolls at a temperature of 21° C., to obtain a uniaxially oriented film. Subsequently, the uniaxially oriented film, while its two ends were being held by clips, was guided to a tenter to be laterally stretched to 3.6 times in the transverse direction in an atmosphere heated to a temperature of 120° C. After that, thermal fixation was performed at a temperature of 200° C. inside the tenter, followed by uniform gradual cooling and then by cooling to 25° C. Thus, an infrared transmitting layer sheet having a total thickness of 50 μm was obtained.

A sheet for a solar battery module having a total thickness of 125 μm was obtained by substantially the same method as the infrared transmitting layer, except that the composition used to obtain the infrared transmitting layer and the composition used to obtain the infrared reflecting layer were extruded in a sheet shape by the extruder A and the extruder B so that the thickness ratio thereof became 50:75 and the layer stacking was performed via a T-die two-layer mouthpiece. Furthermore, using the infrared transmitting layer and the sheet for a solar battery module obtained, a solar battery module was obtained by the method described in the paragraph of “(5) Manufacture and Power Generation Amounts of Solar Battery Modules.” Evaluation results of sheets for solar battery modules and solar battery modules are shown in Table 1.

### Examples 2 to 12 and Comparative Examples 1 to 5

Infrared transmitting layer sheets, sheets for solar battery modules, and solar battery modules were obtained in substantially the same manner as in Example 1, except that the make-ups of the layers (the make-ups of the compositions for obtaining the layers) and layer thickness were as mentioned in Table 1 and Table 2. The make-ups of the layers (mass %) were calculated, by assuming all components constituting the layers to make 100 mass %.

The evaluation results are shown in Tables 1 and 2.

As for Comparative Example 5, the sheet tore at the time of film formation of the infrared reflecting layer and therefore could not be formed as a film.

TABLE 1

| | | | | Example 1 | Example 2 | Example 3 | Example 4 | Example 5 | Example 6 |
|---|---|---|---|---|---|---|---|---|---|
| Infrared | Make-up | Polyester resin | A1 | 95 | 95 | 95 | 95 | 95 | 90 |
| transmitting | (mass %) | Coloration agent | B1 | 5 | 5 | 5 | 5 | 5 | 10 |
| layer | | | B2 | — | — | — | — | — | — |
| | | | B3 | — | — | — | — | — | — |
| | | | B4 | — | — | — | — | — | — |
| | | | B5 | — | — | — | — | — | — |
| | | | B6 | — | — | — | — | — | — |
| | Thickness (μm) | | | 50 | 50 | 50 | 50 | 50 | 10 |
| | Average transmittance 800 to 1200 nm(%) | | | 90< | 90< | 90< | 90< | 90< | 90< |
| Infrared | Make-up | Polyester resin | A1 | 75 | 85 | 45 | 75 | 75 | 75 |
| reflecting | (mass %) | Dispersing | C1 | 5 | 5 | 10 | 5 | 5 | 5 |
| layer | | assistant agent | C2 | 10 | 5 | 10 | 10 | 10 | 10 |
| | | Incompatible polymer | D1 | 10 | 5 | 35 | 10 | 10 | 10 |

| | | | | | | | |
|---|---|---|---|---|---|---|---|
| | Thickness (μm) | 75 | 125 | 75 | 50 | 300 | 75 |
| Sheet for solar | Average reflectance 400 to 600 nm(%) | <5 | <5 | <5 | <5 | <5 | <5 |
| battery module | Average reflectance 800 to 1200 nm(%) | 90 | 83 | 92 | 87 | 94 | 90 |
| | Black color design characteristic | A | A | A | A | A | A |

| | | | | | | |
|---|---|---|---|---|---|---|
| Amount of power generated by solar battery module | 4.14 | 4.13 | 4.16 | 4.14 | 4.16 | 4.15 |

| | | | | Example 7 | Example 8 | Example 9 | Example 10 | Example 11 | Example 12 |
|---|---|---|---|---|---|---|---|---|---|
| Infrared | Make-up | Polyester resin | A1 | 90 | 95 | 90 | 98 | 99 | 95 |
| transmitting | (mass %) | Coloration agent | B1 | — | 5 | — | 2 | 1 | 5 |
| layer | | | B2 | 5 | — | — | — | — | — |
| | | | B3 | 5 | — | 5 | — | — | — |
| | | | B4 | — | — | 5 | — | — | — |
| | | | B5 | — | — | — | — | — | — |
| | | | B6 | — | — | — | — | — | — |
| | Thickness (μm) | | | 50 | 50 | 50 | 50 | 50 | 50 |
| | Average transmittance 800 to 1200 nm(%) | | | 90< | 90< | 90< | 90< | 90< | 90< |
| Infrared | Make-up | Polyester resin | A1 | 75 | 75 | 75 | 75 | 75 | 80 |
| reflecting | (mass %) | Dispersing | C1 | 5 | 5 | 5 | 5 | 5 | 4 |
| layer | | assistant agent | C2 | 10 | 10 | 10 | 10 | 10 | 8 |
| | | Incompatible polymer | D1 | 10 | 10 | 10 | 10 | 10 | 8 |

| | | | | | | | |
|---|---|---|---|---|---|---|---|
| | Thickness (μm) | 75 | 38 | 300 | 300 | 300 | 75 |
| Sheet for solar | Average reflectance 400 to 600 nm(%) | <5 | <5 | <5 | 8 | 18 | <5 |
| battery module | Average reflectance 800 to 1200 nm(%) | 90 | 75 | 94 | 94 | 94 | 88 |
| | Black color design characteristic | A | A | A | A | B | B |

| | | | | | | |
|---|---|---|---|---|---|---|
| Amount of power generated by solar battery module | 4.14 | 4.11 | 4.14 | 4.17 | 4.18 | 4.13 |

TABLE 2

| | | | | Comparative | Comparative | Comparative | Comparative | Comparative |
|---|---|---|---|---|---|---|---|---|
| | | | | Example 1 | Example 2 | Example 3 | Example 4 | Example 5 |
| Infrared | Make-up | Polyester resin | A1 | 95 | 95 | 96 | 95 | 95 |
| transmitting | (mass %) | Coloration agent | B1 | 5 | — | — | — | 5 |
| layer | | | B2 | — | — | 2 | — | — |
| | | | B3 | — | — | 2 | — | — |
| | | | B4 | — | — | — | — | — |
| | | | B5 | — | 5 | — | — | — |
| | | | B6 | — | — | — | 5 | — |
| | Thickness (μm) | | | 50 | 50 | 50 | 50 | 50 |
| | Average transmittance 800 to 1200 nm(%) | | | 90< | <10 | 90< | <10 | 90< |
| Infrared | Make-up | Polyester resin | A1 | 87 | 75 | 75 | 75 | 38 |
| reflecting | (mass %) | Dispersing | C1 | 5 | 5 | 5 | 5 | 10 |
| layer | | assistant agent | C2 | 5 | 10 | 10 | 10 | 10 |
| | | Incompatible polymer | D1 | 3 | 10 | 10 | 10 | 42 |

| | | | | | | |
|---|---|---|---|---|---|---|
| | Thickness (μm) | 75 | 75 | 75 | 75 | 75 |
| Sheet for solar | Average reflectance 400 to 600 nm(%) | <5 | <5 | 25 | <5 | — |
| battery module | Average reflectance 800 to 1200 nm(%) | 78 | <5 | 90 | <5 | — |
| | Black color design characteristic | A | A | C | A | — |

| | | | | | |
|---|---|---|---|---|---|
| Amount of power generated by solar battery module | 4.12 | 4.06 | 4.16 | 4.05 | — |

### INDUSTRIAL APPLICABILITY

A sheet for a solar battery module that, despite being black, is excellent in the reflectiveness for light in the infrared region is provided. Furthermore, by using the sheet for a solar battery module, a solar battery module excellent in power generation efficiency and external appearance can be obtained.

1-8. (canceled)

9. A sheet for a solar battery module comprises an infrared transmitting layer and an infrared reflecting layer containing a polyester resin as a main component, wherein
an average reflectance in a wavelength range of 400 nm to 600 nm is 20% or less, and
the infrared reflecting layer contains an incompatible polymer in an amount greater than or equal to 5 mass % and less than or equal to 40 mass % relative to 100 mass % of all components that constitute the infrared reflecting layer.

10. The sheet according to claim 9, wherein the average reflectance in a wavelength range of 800 nm to 1,200 nm is 85% or greater.

11. The sheet according to claim 9, wherein the infrared transmitting layer contains an infrared transmitting coloration agent.

12. The sheet according to claim 9, wherein the infrared transmitting layer contains a perylene-based pigment.

13. The sheet according to claim 9, wherein the infrared transmitting layer contains a phthalocyanine based blue pigment and/or a dioxazine based violet pigment and a diketopyrrolopyrrole based red pigment.

14. The sheet according to claim 9, wherein the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.

15. A solar battery module comprising a cover member, an obverse side encapsulant, a solar battery cell, a reverse side encapsulant, and a back sheet for the solar battery module positioned in that order from a light receiving side, and
the solar battery module including the sheet for a solar battery module according to claim 9, wherein
the infrared transmitting layer is positioned more to the light receiving surface side than the infrared reflecting layer.

16. The solar battery module according to claim 17, wherein the back sheet for the solar battery module is the sheet for a solar battery module.

17. The sheet according to claim 10, wherein the infrared transmitting layer contains an infrared transmitting coloration agent.

18. The sheet according to claim 10, wherein the infrared transmitting layer contains a perylene-based pigment.

19. The sheet according to claim 11, wherein the infrared transmitting layer contains a perylene-based pigment.

20. The sheet according to claim 10, wherein the infrared transmitting layer contains a phthalocyanine based blue pigment and/or a dioxazine based violet pigment and a diketopyrrolopyrrole based red pigment.

21. The sheet according to claim 11, wherein the infrared transmitting layer contains a phthalocyanine based blue pigment and/or a dioxazine based violet pigment and a diketopyrrolopyrrole based red pigment.

22. The sheet according to claim 12, wherein the infrared transmitting layer contains a phthalocyanine based blue pigment and/or a dioxazine based violet pigment and a diketopyrrolopyrrole based red pigment.

23. The sheet according to claim 10, wherein the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.

24. The sheet according to claim 11, wherein the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.

25. The sheet according to claim 12, wherein the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.

26. The sheet according to claim 13, wherein the incompatible polymer is at least one polymer selected from the group consisting of poly-3-methylphthene-1, poly-4-methylpentene-1, polyvinyl-t-butane, 1,4-trans-poly-2,3-dimethylbutadiene, polyvinyl cyclohexane, polystyrene, polymethylstyrene, polydimethylstyrene, polyfluorostyrene, poly-2-methyl-4-fluorostyrene, polyvinyl-t-butyl ether, cellulose triacetate, cellulose tripropionate, polyvinyl fluoride, amorphous polyolefin, cyclic olefin copolymerized resin, and polychlorotrifluoroethylene.

27. A solar battery module comprising a cover member, an obverse side encapsulant, a solar battery cell, a reverse side encapsulant, and a back sheet for the solar battery module positioned in that order from a light receiving side, and
the solar battery module including the sheet for a solar battery module according to claim 10, wherein
the infrared transmitting layer is positioned more to the light receiving surface side than the infrared reflecting layer.

28. A solar battery module comprising a cover member, an obverse side encapsulant, a solar battery cell, a reverse side encapsulant, and a back sheet for the solar battery module positioned in that order from a light receiving side, and
the solar battery module including the sheet for a solar battery module according to claim 11, wherein
the infrared transmitting layer is positioned more to the light receiving surface side than the infrared reflecting layer.
